(19) United States
(12) Patent Application Publication
(10) Pub. No.: US 2023/0197518 A1
(43) Pub. Date: Jun. 22, 2023

(54) SEMICONDUCTOR DEVICE AND METHOD FOR MANUFACTURING SAME

(71) Applicants: Kabushiki Kaisha Toshiba, Tokyo (JP); Toshiba Electronic Devices & Storage Corporation, Tokyo (JP)

(72) Inventor: Shinji Onzuka, Nonoichi Ishikawa (JP)

(21) Appl. No.: 17/938,999

(22) Filed: Sep. 7, 2022

(30) Foreign Application Priority Data
Dec. 22, 2021 (JP) 2021-207807
Aug. 16, 2022 (JP) 2022-129700

(51) Int. Cl. H01L 21/78; H01L 21/268; H01L 29/861; H01L 29/78

(52) U.S. Cl. CPC H01L 21/78; H01L 21/268; H01L 29/8613; H01L 29/7813

(57) ABSTRACT

A semiconductor device includes a semiconductor part, a first electrode and a second electrode. The semiconductor part includes a first semiconductor layer of a first conductivity type and a second semiconductor layer of a second conductivity type. The first electrode is provided on a front surface of the semiconductor part. The second semiconductor layer is provided between the first semiconductor layer and the first electrode. The second electrode is provided on a back surface of the semiconductor part at a side opposite to the front surface. The second electrode includes an extension part extending outward from an outer edge of the back surface.

### CROSS-REFERENCE TO RELATED APPLICATIONS

This application is based upon and claims the benefit of priority from Japanese Patent Application No. 2021-207807, filed on Dec. 22, 2021, and Japanese Patent Application No. 2022-129700, filed on Aug. 16, 2022; the entire contents of all of which are incorporated herein by reference.

### FIELD

Embodiments relate to a semiconductor device and a method for manufacturing the same.

### BACKGROUND

A semiconductor device bonded to a mounting substrate has the bonding strength affected by the connection strength between a connection member such as a solder material or the like and an electrode of the mounting substrate. Thus, it is preferable to increase the connection strength between the electrode and the connection member by increasing the connection area between the electrode and the connection member.

### SUMMARY

In certain embodiments, a method for manufacturing a semiconductor device comprises providing a metal film on a back surface of a semiconductor wafer and forming a plurality of first grooves through the metal film. Each of the plurality of first grooves has a first width and is configured to separate the metal film into a plurality of first electrodes.

In some embodiments, the method for manufacturing a semiconductor device further comprises forming a plurality of second grooves from a front surface of the semiconductor wafer and to the back surface. Each of the plurality of second grooves has a second width that is greater than the first width, and each of the plurality of second grooves is configured to separate the semiconductor wafer into a plurality of semiconductor chips. In further embodiments, each of the plurality of semiconductor chips comprises a portion of the semiconductor wafer and a first electrode of the plurality of first electrodes.

In certain embodiments of the method for manufacturing a semiconductor device, the plurality of first electrodes are arranged in a first direction parallel to the back surface of the semiconductor wafer, and are further arranged in a second direction parallel to the back surface of the semiconductor wafer. In some embodiments, the second direction is orthogonal to the first direction.

In further embodiments, the method for manufacturing a semiconductor device further comprises forming the plurality of second grooves by dry etching the semiconductor wafer and not the plurality of first electrodes. In some embodiments, the method for manufacturing a semiconductor device further comprises forming the plurality of second grooves by dry etching the semiconductor device such that an etching rate of each of the plurality of first electrodes is less than an etching rate of the semiconductor wafer.

In certain embodiments, the method for manufacturing a semiconductor device further comprises irradiating laser light on the metal film provided on the back surface of the semiconductor wafer. In some embodiments, the method for manufacturing a semiconductor device still further comprises scanning the laser light to divide the metal film along a dicing line provided at the front surface of the semiconductor wafer.

In further embodiments of the method for manufacturing a semiconductor device, the semiconductor wafer includes damage caused by the irradiating of the laser light irradiation, and the damage is removed through the forming the plurality of second grooves.

In some embodiments, the method for manufacturing a semiconductor device further comprises forming a protective film on the front surface of the semiconductor wafer. In certain embodiments, the method for manufacturing a semiconductor device further comprises forming a plurality of third grooves configured to divide the protective film into a plurality of etching masks on the front surface of the semiconductor wafer. In some embodiments, each of the plurality of third grooves has a third width and is formed by irradiating the protective film with laser light and scanning the laser light along a dicing line provided at the front surface of the semiconductor wafer. In certain embodiments, the third width is greater than the first width. In further embodiments, the method for manufacturing a semiconductor device further comprises forming each of the plurality of second grooves by selectively removing the semiconductor wafer using the plurality of etching masks.

In certain embodiments of the method for manufacturing a semiconductor device the semiconductor wafer comprises a first semiconductor layer. In some embodiments, a plurality of second semiconductor layers are disposed along a front surface of the wafer.

In further embodiments, a plurality of insulating films cover the plurality of second semiconductor layers. In some embodiments each of the plurality of insulating films is separated by a dicing line.

In certain embodiments, a plurality of second electrodes are provided on the plurality of insulating films, each of the plurality of second electrodes being in electrical contact with a respective second semiconductor layer of the plurality of second semiconductor layers via one of a plurality of contact holes provided in the plurality of insulating films.

In some embodiments, a protective film is formed on the metal film. In certain embodiments, the protective film is removed from the metal film after the plurality of first grooves is formed in the metal film.

In some embodiments, a semiconductor device comprises a semiconductor, the semiconductor including a first semiconductor layer of a first conductivity type and a second semiconductor layer of a second conductivity type. In certain embodiments, the semiconductor further comprises a first electrode provided on a back surface of the semiconductor at a side opposite to a front surface of the semiconductor wafer.

In further embodiments, a second electrode is provided on the front surface of the semiconductor. In some embodiments, the second semiconductor layer is provided between the first semiconductor layer and the second electrode. In certain embodiments, the first electrode comprises an extension that extends laterally beyond an outer edge of the back surface of the semiconductor.

In some embodiments, the first electrode has a first surface facing the back surface of the semiconductor. In certain embodiments, a first surface area of the first surface is between about five percent and about fifteen percent larger than a second surface area of the back surface.

In further embodiments, the extension of the first electrode surrounds a region of the first electrode that contacts the back surface of the semiconductor. In some embodiments, the first electrode contacts an entirety of the back surface of the semiconductor. In certain embodiments, the first electrode contacts the outer edge of the back surface of the semiconductor.

In some embodiments, the extension of the first electrode extends in a direction parallel to the back surface of the semiconductor. In certain embodiments, the first electrode includes a first surface and a second surface. In some embodiments, the first surface contacts the back surface of the semiconductor. In certain embodiments, the second surface is disposed at a side opposite to the first surface and has a first surface area. In further embodiments, the back surface of the semiconductor has a second surface area, and the front surface of the semiconductor has a third surface area. In some embodiments, the first surface area is greater than the second surface area and the third surface area.

In some embodiments, the first surface area is between about five percent and about fifteen percent larger than both of the second surface area and the third surface area.

In certain embodiments, the semiconductor device further comprises a control electrode provided between the first electrode and the second electrode. In some embodiments, the control electrode is provided in the semiconductor.

In further embodiments, the control electrode faces the first semiconductor layer and the second semiconductor layer with a first insulating film interposed. In some embodiments, the semiconductor further includes a third semiconductor layer of the first conductivity type. In certain embodiments, the third semiconductor layer is partially provided between the second electrode and the second semiconductor layer. In further embodiments, the third semiconductor layer contacts the first insulating film.

### BRIEF DESCRIPTION OF THE DRAWINGS

FIG. 1 is a schematic cross-sectional view showing a semiconductor device according to an embodiment;

FIG. 2 is a schematic plan view showing the bonding surface of the semiconductor device according to the embodiment;

FIG. 3 is a schematic plan view showing a semiconductor wafer according to the embodiment;

FIGS. 4A to 5C are schematic cross-sectional views showing manufacturing processes of the semiconductor device according to the embodiment;

FIG. 6 is a schematic cross-sectional view showing a semiconductor device according to a comparative example; and

FIG. 7 is a schematic cross-sectional view showing a semiconductor device according to a variation of the embodiment.

### DETAILED DESCRIPTION

According to one embodiment, a semiconductor device includes a semiconductor part, a first electrode and a second electrode. The semiconductor part includes a first semiconductor layer of a first conductivity type and a second semiconductor layer of a second conductivity type. The first electrode is provided on a back surface of the semiconductor part at a side opposite to the front surface. The first electrode includes an extension part extending outward from an outer edge of the back surface. The second electrode is provided on a front surface of the semiconductor part. The second semiconductor layer is provided between the first semiconductor layer and the second electrode,

Embodiments will now be described with reference to the drawings. The same portions inside the drawings are marked with the same numerals; a detailed description is omitted as appropriate; and the different portions are described. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

There are cases where the dispositions of the components are described using the directions of XYZ axes shown in the drawings. The X-axis, the Y-axis, and the Z-axis are orthogonal to each other. Hereinbelow, the directions of the X-axis, the Y-axis, and the Z-axis are described as an X-direction, a Y-direction, and a Z-direction. Also, there are cases where the Z-direction is described as upward and the direction opposite to the Z-direction is described as downward.

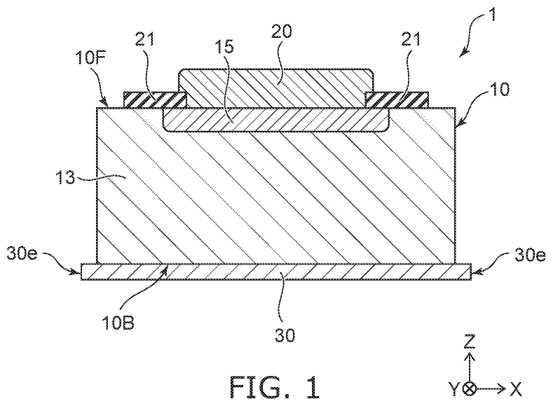

FIG. 1 is a schematic cross-sectional view showing a semiconductor device 1 according to an embodiment. The semiconductor device 1 is, for example, a diode. The embodiment is not limited to a diode and may be a MOSFET, etc.

As shown in FIG. 1, the semiconductor device 1 includes a semiconductor part 10, a second electrode 20, and a first electrode 30. The semiconductor part 10 is, for example, silicon. The second electrode 20 is provided on a front surface 10F of the semiconductor part 10. The second electrode 20 is, for example, an anode electrode. The first electrode 30 is provided on a back surface 10B. The back surface 10B is at the side opposite to the front surface 10F. The first electrode 30 is, for example, a cathode electrode.

The semiconductor part 10 includes, for example, a first semiconductor layer 13 of a first conductivity type, and a second semiconductor layer 15 of a second conductivity type. The first conductivity type is, for example, an n-type. The second conductivity type is, for example, a p-type.

The first semiconductor layer 13 extends between the second electrode 20 and the first electrode 30. The second semiconductor layer 15 is provided between the first semiconductor layer 13 and the second electrode 20. The second semiconductor layer 15 is electrically connected to the second electrode 20. The second semiconductor layer 15 is, for example, a p-type anode layer.

The semiconductor device 1 further includes an insulating film 21. The insulating film 21 partially covers the front surface 10F of the semiconductor part 10. The insulating film 21 covers, for example, the outer edge of the second semiconductor layer 15. The second electrode 20 is electrically connected to the second semiconductor layer 15 via a contact hole provided in the insulating film 21.

The first electrode 30 covers the back surface 10B of the semiconductor part 10. The first electrode 30 is electrically connected to the first semiconductor layer 13. The first electrode 30 includes an extension part 30e that extends outward from the outer edge of the back surface 10B of the semiconductor part 10. The extension part 30e extends from the outer edge of the back surface 10B, for example, in a +X direction and a −X direction that are parallel to the back surface 10B. The extension part 30e has, for example, the same thickness as a thickness of the first electrode 30 in the region contacting the semiconductor part 10.

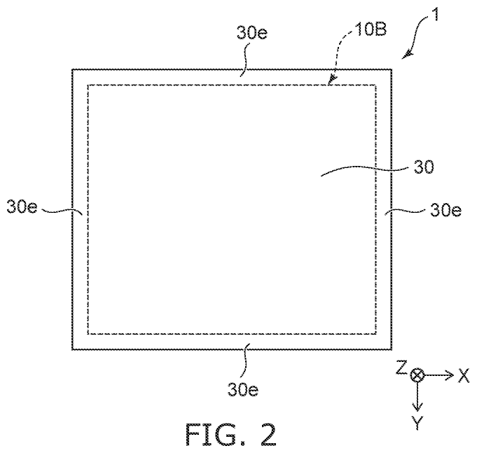

FIG. 2 is a schematic plan view showing the bonding surface of the semiconductor device 1 according to the embodiment. FIG. 2 illustrates the back surface of the first electrode 30. The back surface is at the side opposite to the front surface that contacts the semiconductor part 10.

As shown in FIG. 2, the first electrode 30 covers the entire back surface 10B of the semiconductor part 10. The extension part 30e of the first electrode 30 extends along the outer edge of the back surface 10B and surrounds the region of the first electrode 30 that contacts the back surface 10B.

The first electrode 30 includes a back surface that is at the side opposite to the front surface contacting the back surface 10B of the semiconductor part 10. The bonding surface of the semiconductor device 1 is the back surface of the first electrode 30. The surface area of the back surface of the first electrode 30 is greater than the surface area of the back surface 10B of the semiconductor part 10. Also, the surface area of the back surface of the first electrode 30 is greater than the surface area of the front surface 10F of the semiconductor part 10.

The extension part 30e surrounds the semiconductor part 10 in a plan view parallel to the back surface 10B. Such an extension part 30e provides the enlarged bonding surface of the first electrode 30, and increases the bonding strength of the semiconductor device 1.

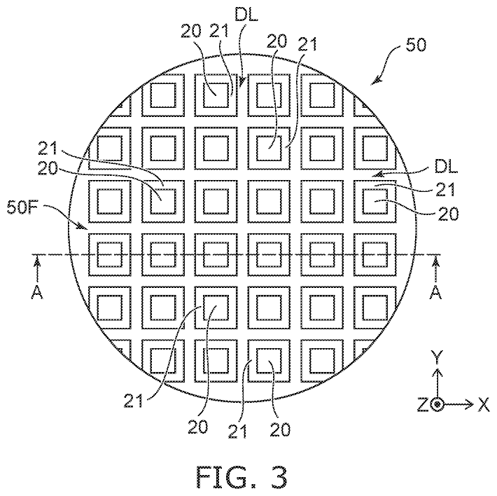

FIG. 3 is a schematic plan view showing a semiconductor wafer 50 according to the embodiment. The semiconductor wafer 50 is used for manufacturing the semiconductor device 1. The semiconductor wafer 50 is, for example, an n-type silicon wafer. FIG. 3 shows a front surface 50F of the semiconductor wafer 50.

Multiple second electrodes 20 and multiple insulating films 21 are provided on the front surface 50F of the semiconductor wafer 50. The second electrodes 20 and the insulating films 21 are arranged in the X-direction and the Y-direction. A dicing line DL is provided between the insulating films 21 that are next to each other. The dicing line DL extends, for example, in the X-direction and the Y-direction.

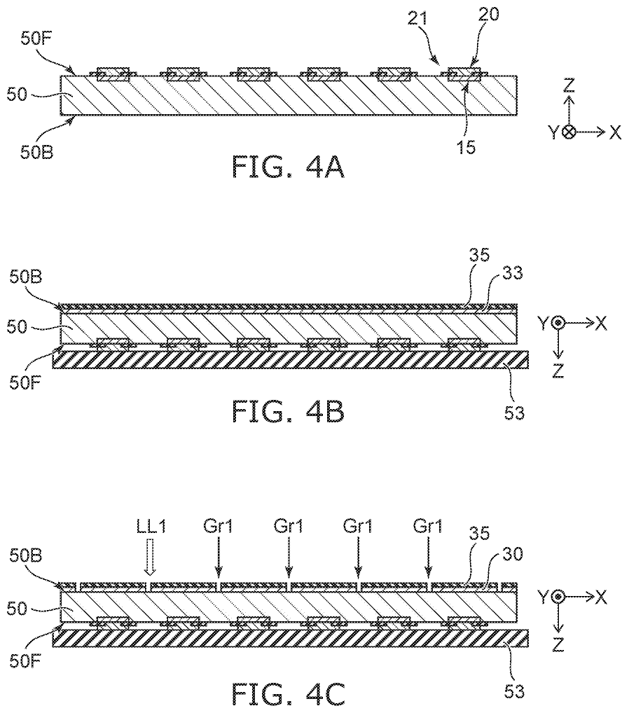

A method for manufacturing the semiconductor device 1 will now be described with reference to FIGS. 4A to 5C. FIGS. 4A to 5C are schematic cross-sectional views showing manufacturing processes of the semiconductor device 1 according to the embodiment.

FIG. 4A is a cross-sectional view of the semiconductor wafer 50 along line A-A shown in FIG. 3. Multiple second semiconductor layers 15 are provided at the front surface 50F side of the semiconductor wafer 50. The insulating film 21 is provided to cover the second semiconductor layer 15. The second electrode 20 is provided on the insulating film 21 and electrically connected to the second semiconductor layer 15 via a contact hole provided in the insulating film 21. The second electrode 20 includes, for example, at least one of titanium (Ti), tungsten (W), nickel (Ni), aluminum (Al), aluminum silicon (AlSi), gold (Au), or palladium (Pd). The insulating film 21 can include, for example, a silicon oxide film, polyimide, etc.

The semiconductor wafer 50 is thinned by, for example, polishing or etching a back surface 50B side. The semiconductor wafer 50 is thinned to, for example, a thickness of not more than 150 micrometers (μm).

Then, a metal film 33 is formed on the back surface of the semiconductor wafer 50. The metal film 33 includes, for example, at least one of titanium (Ti), nickel (Ni), aluminum (Al), AISi, gold (Au), silver (Ag), AuAg, or copper (Cu), The metal film 33 is formed using, for example, sputtering or plating.

As shown in FIG. 4B, the thinned semiconductor wafer 50 is adhered on a resin sheet 53. The resin sheet 53 is adhered to the front surface 50F side of the semiconductor wafer 50. The resin sheet 53 includes polyolefin, PET, vinyl chloride, etc. The resin sheet 53 is adhered to the semiconductor wafer 50 via, for example, an acrylic adhesive material.

Then, a protective film 35 is formed on the metal film 33. The protective film 35 is formed by, for example, coating and curing a resin member. The protective film 35 includes, for example, polyvinyl alcohol, polyethylene glycol, polyglycerin, etc. The protective film 35 may be a photoresist film.

As shown in FIG. 4C, the metal film 33 and the protective film 35 are divided on the back surface 50B of the semiconductor wafer 50. The metal film 33 and the protective film 35 are divided by, for example, forming a groove Gr1 by irradiating laser light LL1. The laser light LL1, for example, is scanned along the dicing line DL (see FIG. 3); and the groove Gr1 extends along the dicing line DL of the front surface 50F side. Thereby, the metal film 33 is separated into the multiple first electrodes 30.

The protective film 35 may be patterned using photolithography. Subsequently, the multiple first electrodes 30 may be formed on the back surface 50B of the semiconductor wafer 50 by etching the metal film 33 using the protective film 35 as a mask. In such a case, the metal film 33 is selectively removed using, for example, RIE (Reactive Ion Etching) or wet etching.

Then, the protective film 35 is removed from the first electrode 30 (i.e., the metal film 33). When the protective film 35 is a water-soluble resin, the protective film 35 is removed by rinsing with water. When the protective film 35 is a photoresist, the protective film 35 is removed by, for example, oxygen ashing.

As shown in FIG. 5A, the resin sheet 53 at the front surface 50F side is peeled after adhering a resin sheet 55 on the back surface 50B of the semiconductor wafer 50. The resin sheet 55 includes, for example, the same material as the resin sheet 53.

A protective film 25 is formed on the front surface 50F of the semiconductor wafer 50. The protective film 25 covers the second electrode 20 and the insulating film 21 on the front surface 50F. The protective film 25 is formed by, for example, coating and curing a resin member. The protective film 25 includes, for example, polyvinyl alcohol, polyethylene glycol, polyglycerin, etc. The protective film 25 may be a photoresist film.

As shown in FIG, 5B, the protective film 25 is divided by, for example, irradiating laser light LL3. The laser light LL3 is scanned along the dicing line DL (see FIG. 3), and forms a groove Gr3 that divides the protective film 25. The spot diameter of the laser light LL3 is greater than the spot diameter of the laser light LL1 (see FIG. 4C). Therefore, the width of the groove Gr3 is greater than the width of the groove Gr1. The irradiation of the laser light LL3 also removes a portion of the semiconductor wafer 50. Alignment marks, monitor patterns, etc., that are provided on the dicing line DL are removed thereby, and the front surface 50F of the semiconductor wafer 50 is exposed at the bottom surface of the groove Gr3. The protective film 25 may be patterned using photolithography.

As shown in FIG. 50, a groove Gr2 is formed by etching the semiconductor wafer 50 using the protective film 25 as a mask. The semiconductor wafer 50 is selectively removed using, for example, dry etching. The semiconductor wafer 50 may be selectively removed by wet etching. The groove Gr2 extends in the X-direction and the Y-direction along the dicing line DL (see FIG. 3). The semiconductor wafer 50 is divided into the multiple semiconductor parts 10 and divided into the multiple semiconductor device 1 chips by the groove Gr2.

The groove Gr2 has a depth enough to reach the back surface 50B from the front surface 50F of the semiconductor wafer 50. The groove Gr2 communicates with the space between the first electrodes 30 next to each other on the back surface 50B (i.e., the groove Gr1), The width of the groove Gr2 is greater than the width of the groove Gr1. Therefore, the extension part 30e of the first electrode 30 is formed along the outer edge of the back surface 10B of the semiconductor part 10. The extension part 30e extends in a direction parallel to the back surface 10B (see FIG. 1).

The semiconductor wafer 50 is etched, for example, under conditions such that the first electrode 30 is not etched, or the etching rate of the first electrode 30 is slower than the etching rate of the semiconductor wafer 50.

According to the manufacturing method of the embodiment, the damage layer of the semiconductor wafer 50 is removed by forming the groove Gr2. The damage layer is formed at the bottom surface of the groove Gr1 by the laser light LL1 (see FIG. 4C). Also, other damage layer of the semiconductor wafer 50 is removed through the process of forming the groove Gr2. The other damage is formed at the bottom surface of the groove Gr3 by the irradiation of the laser light LL3 (see FIG. 5B). In other words, it is possible to remove the damage layers of the semiconductor part 10 caused by the irradiation of the laser light LL1 and the laser light LL3.

Then, the protective film 25 is removed which covers the second electrode 20 and the insulating film 21. When the protective film 25 is a water-soluble resin, the protective film 25 is removed by rinsing with water. When the protective film 25 is a photoresist, the protective film 25 is removed by, for example, oxygen ashing.

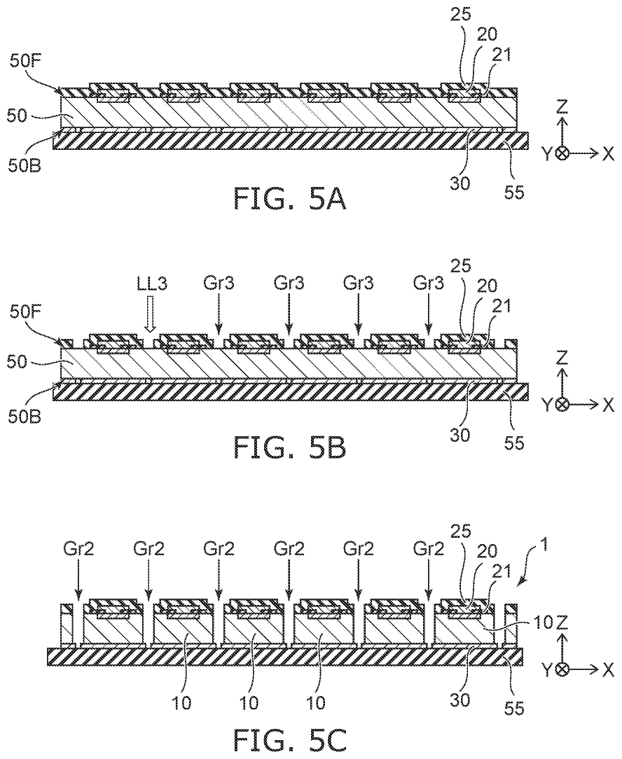

FIG. 6 is a schematic cross-sectional view showing a semiconductor device 2 according to a comparative example. Label figure as prior art. The semiconductor device 2 is formed by dividing the semiconductor wafer 50 into chips, for example, using a dicing blade. Therefore, the metal film 33 formed on the back surface 50B of the semiconductor wafer 50 (see FIG. 4B) also is cut by a dicing blade.

In the semiconductor device 2, for example, there are cases where burr 30f generates at the outer edge of the first electrode 30, and extends in a direction perpendicular to the back surface 10B of the semiconductor part 10. When the first electrode 30 extends in the rotation direction of the dicing blade, the burr 30f is generated due to the ductility of the metal included in the first electrode 30. Such burr 30f causes, for example, a gap between the first electrode 30 and the mounting substrate when bonding the semiconductor device 2 on the mounting substrate. Thus, voids, etc., are formed inside the bonding member, and the bonding strength of the semiconductor device 2 is reduced.

In contrast, the semiconductor device 1 according to the embodiment includes the extension part 30e of the first electrode 30 that extends in a direction parallel to the back surface 10B of the semiconductor part 10. Therefore, the extension part 30e does not impair the bonding of the semiconductor device 1 on the mounting substrate. Moreover, the extension part 30e enlarges the bonding surface and increases the bonding strength of the semiconductor device 1.

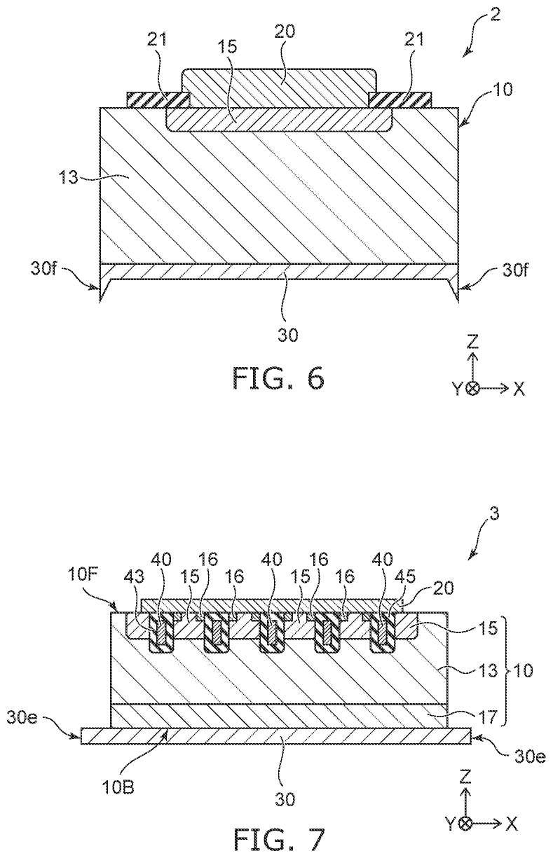

FIG. 7 is a schematic cross-sectional view showing a semiconductor device 3 according to a variation of the embodiment. The semiconductor device 3 is, for example, a MOSFET.

As shown in FIG. 7, the semiconductor device 3 includes the semiconductor part 10, the second electrode 20, the first electrode 30 and a control electrode 40. The second electrode 20 is provided on a front surface 10F of the semiconductor part 10. The second electrode 20 is, for example, a source electrode. The first electrode 30 is provided on a back surface 10B. The back surface 10E3 is at the side opposite to the front surface 10F. The first electrode 30 is, for example, a drain electrode.

The semiconductor part 10 includes, the first semiconductor layer 13 of the first conductivity type, and the second semiconductor layer 15 of the second conductivity type, a third semiconductor layer 16 of the first conductivity type and a fourth semiconductor layer 17 of the first conductivity type.

In the example, the first semiconductor layer 13 is, for example, an n-type drift layer. The first semiconductor layer 13 extends between the second electrode 20 and the first electrode 30. The second semiconductor layer 15 is, for example, a p-type body layer. The second semiconductor layer 15 is provided between the first semiconductor layer 13 and the second electrode 20. The third semiconductor layer 16 is, for example, an n-type source layer. The third semiconductor layer 16 is partially provided on the second semiconductor layer 15 between the second semiconductor layer 15 and the second electrode 20. The fourth semiconductor layer 17 is, for example, an n-type drain layer. The fourth semiconductor layer 17 is provided between the first semiconductor layer 13 and the second electrode 30.

The control electrode 40 is provided in the semiconductor part 10 between the second electrode 20 and the first electrode 30. In the semiconductor part 10, the control electrode 40 faces the first semiconductor layer 13 and the second semiconductor layer 15 with a first insulating film 43 interposed. Moreover, the control electrode 40 faces the second electrode 20 with a second insulating film 45 interposed. The control electrode 40 is, for example, a gate electrode. The first insulating film 43 is, for example, a gate insulating film. The second insulating film 45 is, for example, an interlayer insulating film.

The third semiconductor layer 16 contacts the first insulating film 43. The second semiconductor layer 15 faces the control electrode 40 via the first insulating film between the first semiconductor layer 13 and the third semiconductor layer 16. The second electrode 20 is electrically connected to the second semiconductor layer 15 and the third semiconductor layer 16.

The first electrode 30 covers the back surface 10B of the semiconductor part 10. The first electrode 30 is electrically connected to the fourth semiconductor layer 17. Also in the example, the first electrode 30 includes an extension part 30e that extends outward from the outer edge of the back surface 10B of the semiconductor part 10. The extension part 30e extends outside from the outer edge of the back surface 10B, for example, in a +X direction and a −X direction that are parallel to the back surface 10B. The extension part 30e has, for example, the same thickness as a thickness of the second electrode 30 in the region contacting the semiconductor part 10.

While certain embodiments have been described, these embodiments have been presented by way of example only, and are not intended to limit the scope of the inventions. Indeed, the novel embodiments described herein may be embodied in a variety of other forms; furthermore, various omissions, substitutions, and changes in the form of the embodiments described herein may be made without departing from the spirit of the inventions. The accompanying claims and their equivalents are intended to cover such forms or modifications as would fall within the scope and spirit of the invention.

What is claimed is:

1. A method for manufacturing a semiconductor device, the method comprising:
providing a metal film on a back surface of a semiconductor wafer;
forming a plurality of first grooves through the metal film, each of the plurality of first grooves having a first width and configured to separate the metal film into a plurality of first electrodes;
forming a plurality of second grooves from a front surface of the semiconductor wafer and to the back surface, each of the plurality of second grooves having a second width, greater than the first width, and configured to separate the semiconductor wafer into a plurality of semiconductor chips, each of the plurality of semiconductor chips comprising a portion of the semiconductor wafer and a first electrode of the plurality of first electrodes.

2. The method according to claim 1, wherein
the plurality of first electrodes are arranged in a first direction parallel to the back surface of the semiconductor wafer and in a second direction parallel to the back surface of the semiconductor wafer, the second direction being orthogonal to the first direction.

3. The method according to claim 1, further comprising:
forming the plurality of second grooves by dry etching the semiconductor wafer and not the plurality of first electrodes,

4. The method according to claim 1, further comprising:
forming the plurality of second grooves by dry etching the semiconductor device such that an etching rate of each of the plurality of first electrodes is less than an etching rate of the semiconductor wafer.

5. The method according to claim 1, further comprising:
irradiating laser light on the metal film provided on the back surface of the semiconductor wafer; and
scanning the laser light to divide the metal film along a dicing line provided at the front surface of the semiconductor wafer.

6. The method according to claim 5, wherein
the semiconductor wafer includes damage caused by the irradiating of the laser light irradiation, and the damage is removed through the forming the plurality of second grooves.

7. The method according to claim 1, further comprising:
forming a protective film on the front surface of the semiconductor wafer;
forming a plurality of third grooves configured to divide the protective film into a plurality of etching masks on the front surface of the semiconductor wafer, each of the plurality of third grooves having a third width and formed by irradiating the protective film with laser light and scanning the laser light along a dicing line provided at the front surface of the semiconductor wafer, wherein the third width is greater than the first width; and
forming each of the plurality of second grooves by selectively removing the semiconductor wafer using the plurality of etching masks.

8. The method according to claim 1, wherein the semiconductor wafer comprises a first semiconductor layer, and wherein a plurality of second semiconductor layers are disposed along a front surface of the wafer.

9. The method according to claim 8, wherein a plurality of insulating films cover the plurality of second semiconductor layers, each of the plurality of insulating films being separated by a dicing line.

19. The method according to claim 9, wherein a plurality of second electrodes are provided on the plurality of insulating films, and wherein each of the plurality of second electrodes are in electrical contact with a respective second semiconductor layer of the plurality of second semiconductor layers via one of a plurality of contact holes provided in the plurality of insulating films.

11. The method of claim 1, wherein a protective film is formed on the metal film, and wherein the protective film is removed from the metal film after the plurality of first grooves is formed in the metal film.

12. A semiconductor device, comprising;
a semiconductor including a first semiconductor layer of a first conductivity type and a second semiconductor layer of a second conductivity type;
a first electrode provided on a back surface of the semiconductor at a side opposite to a front surface of the semiconductor wafer,
a second electrode provided on the front surface of the semiconductor, the second semiconductor layer being provided between the first semiconductor layer and the second electrode,
wherein the first electrode comprises an extension that extends laterally beyond an outer edge of the back surface of the semiconductor.

13. The device according to claim 12, wherein the first electrode has a first surface facing the back surface of the semiconductor, a first surface area of the first surface is between about five percent and about fifteen percent larger than a second surface area of the back surface.

14. The device according to claim 12, wherein
the extension of the first electrode surrounds a region of the first electrode that contacts the back surface of the semiconductor.

15. The device according to claim 12, wherein
the first electrode contacts an entirety of the back surface of the semiconductor.

16. The device according to claim 12, wherein
the first electrode contacts the outer edge of the back surface of the semiconductor.

17. The device according to claim 12, wherein
the extension of the first electrode extends in a direction parallel to the back surface of the semiconductor.

18. The device according to claim 12, wherein
the first electrode includes a first surface and a second surface, the first surface contacting the back surface of the semiconductor, the second surface being at a side opposite to the first surface and having a first surface area,
the back surface of the semiconductor has a second surface area, and
the front surface of the semiconductor has a third surface area, and wherein
the first surface area is greater than the second surface area and the third surface area.

19. The device according to claim 12, further comprising:
a control electrode provided between the first electrode and the second electrode, the control electrode being provided in the semiconductor,
the control electrode facing the first semiconductor layer and the second semiconductor layer with a first insulating film interposed,
the semiconductor further including a third semiconductor layer of the first conductivity type, the third semiconductor layer being partially provided between the second electrode and the second semiconductor layer, the third semiconductor layer contacting the first insulating film.

20. The device according to claim 18, wherein the first surface area is between about five percent and about fifteen percent larger than both of the second surface area and the third surface area.
